(19) United States
(12) Patent Application Publication
(10) Pub. No.: US 2002/0179934 A1
(43) Pub. Date: Dec. 5, 2002

(54) MOS field effect transistor structure and method of manufacture

(76) Inventors: Shui-Ming Cheng, Hsinchu Hsien (TW); Yao-Chin Cheng, Hsinchu (TW); Yu-Shyang Huang, Taipei Hsien (TW); Chih-Chien Liu, Taipei (TW)

Correspondence Address: J.C. Patents, Suite 250, 4 Venture, Irvine, CA, 92618, US

(21) Appl. No.: 10/085,666

(22) Filed: Feb. 26, 2002

Related U.S. Application Data
(62) Division of application No. 09/867,327, filed on May 29, 2001.

(51) Int. Cl. H01L 31/0336

(52) U.S. Cl. 257/199

(57) ABSTRACT

A method of manufacturing a metal-oxide-semiconductor field effect (MOSFET) device. A substrate having an isolating structure thereon is provided. A gate dielectric layer and a conductive layer are sequentially formed over the substrate. The conductive layer and the gate dielectric layer are patterned to form a gate structure. A low dielectric constant material spacer is formed on the sidewall of the gate structure. A source drain region is formed in the substrate on each side of the gate structure.

### BACKGROUND OF THE INVENTION

1. Field of Invention

The present invention relates to a method of fabricating an integrated circuit. More particularly, the present invention relates to a type of metal-oxide-semiconductor (MOS) field effect transistor and its method of manufacture.

2. Description of Related Art

Due to relatively low power consumption, metal-oxide-semiconductor (MOS) transistors are commonly used in high-density integrated circuits. As size of the MOS transistors reduces to deep submicron dimensions through an increase in the level of integration, parasitic resistance and parasitic capacitance become important factors that may affect operating speed of the device. Consequently, parasitic resistance and capacitance must be reduced as much as possible to increase the operating speed of the device. A method of lowering parasitic resistance includes strengthening the source/drain structure. However, this method cannot increase the operating speed of a device. This is because the ultra-thin oxide layer between the polysilicon gate and the substrate produces a high gate capacitance and the oxide/nitride spacer between the source/drain region and the polysilicon gate produces a high parasitic capacitance. One method of reducing the gate oxide capacitance in the ultra-thin oxide layer between the polysilicon gate and the substrate is to increase thickness of the gate oxide layer. However, increasing thickness of the gate oxide layer often lowers current driving capacity of the device. Ultimately, operating speed of the device remains unchanged. The only alternative method for increasing the operating speed of a deep submicron type MOS transistor is to reduce parasitic capacitance.

### SUMMARY OF THE INVENTION

Accordingly, one object of the present invention is to provide a type of metal-oxide-semiconductor (MOS) field effect transistor having a gate terminal and a pair of source/drain terminals such that parasitic capacitance between the gate terminal and the source/drain terminal is reduced resulting in a higher operating speed for the device.

A second object of the invention is to provide a MOS field effect transistor having internal spacers fabricated from a low dielectric constant material so that parasitic capacitance due to the spacer is reduced leading to a higher operating speed for the device.

This invention provides a method of manufacturing a MOS device. A substrate having an isolating structure thereon is provided. A gate dielectric layer and a conductive layer are sequentially formed over the substrate. The conductive layer and the gate dielectric layer are patterned to form a gate structure. Thereafter, spacers fabricated from a low dielectric constant (low-k) material are formed over the sidewalls of the gate structure. Finally, a source drain region is formed in the substrate on each side of the gate structure.

One major aspect of this invention is the fabrication of special low-k spacers on the sidewalls of the gate structure instead of silicon nitride or silicon oxide in the conventional method. Hence, parasitic capacitance resulting from the spacers is reduced. In addition, to reduce parasitic capacitance of spacers, low-k spacers may be added to the junction area between the gate structure and the conventional silicon nitride or silicon oxide spacers. Similarly, low-k spacers may be added to the junction area between the substrate and the conventional silicon nitride or silicon oxide spacers.

This invention also provides a type of metal-oxide-semiconductor (MOS) field effect transistor. The MOS transistor structure includes a substrate, a gate structure over the substrate, a low dielectric constant material spacers on each sidewall of the gate structure and a source/drain region in the substrate on each side of the gate structure. The gate structure further includes a gate conductive layer and a gate dielectric layer between the gate conductive layer and the substrate. The structure further includes a lightly doped source/drain region underneath the low dielectric constant material spacer adjacent to the source/drain region.

Furthermore, the aforementioned MOS field effect transistor may also includes a composite spacer structure on each sidewall of the gate structure. The composite spacer includes a dielectric spacer and a low dielectric constant spacer. The low dielectric constant spacer is formed in the junction area between the dielectric spacer and the gate structure and in the junction area between the dielectric spacer and the substrate.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A through 1D are schematic cross-sectional views showing the progression of steps for producing a MOS field effect transistor according to a first preferred embodiment of this invention; and

FIGS. 2A and 2B are schematic cross-sectional views showing the progression of steps for producing a MOS field effect transistor according to a second preferred embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts,

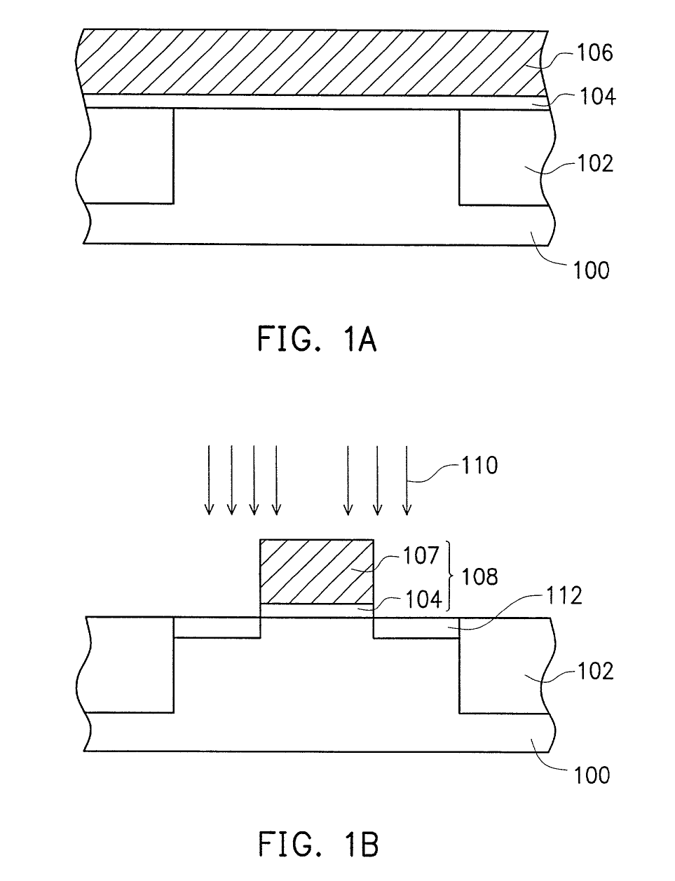

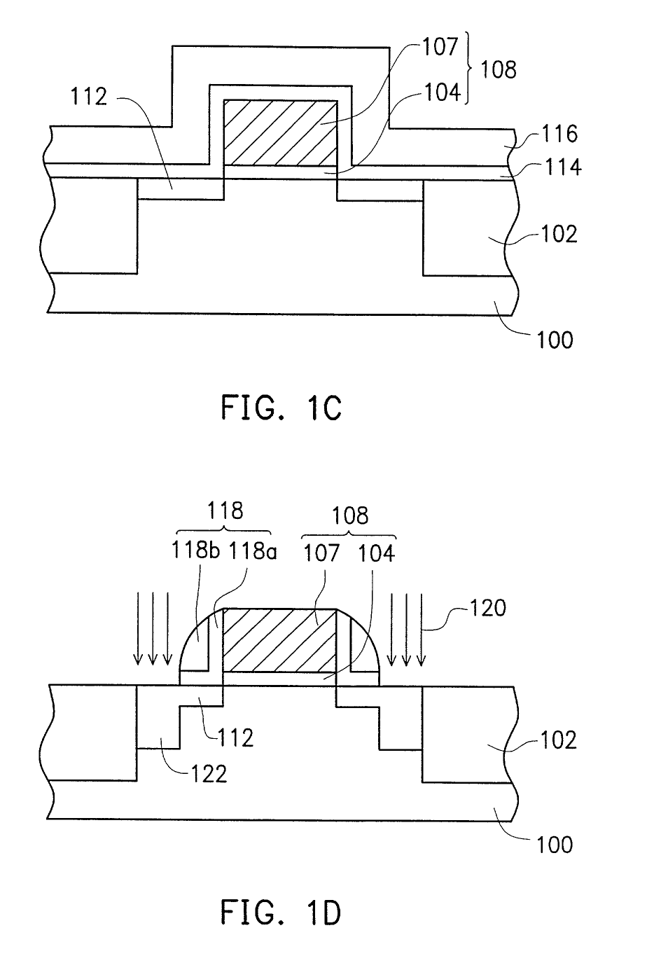

FIGS. 1A through 1D are schematic cross-sectional views showing the progression of steps for producing a MOS field effect transistor according to a first preferred embodiment of this invention. As shown in FIG. 1A, a substrate 100 such as a silicon substrate is provided. Device isolation structures 102 are formed in the substrate 100. The device isolation structures 102, for example, can be field oxide layers formed by local oxidation of silicon (LOCOS) or shallow trench isolation (STI) structures. A gate dielectric layer 104 is formed over the substrate 100. The gate dielectric layer 104 having a thickness of about 22 Å can be a silicon oxide layer formed, for example, by thermal oxidation. A conductive layer 106 is formed over the gate dielectric layer 104. The conductive layer 106 can be a doped polysilicon layer, for example. The steps for forming the doped polysilicon layer 106 include, for example, depositing an undoped polysilicon layer over the gate dielectric layer 104 in a low pressure chemical vapor deposition (LPCVD) process, implanting dopants into the polysilicon layer and finally activating the dopants by annealing. The conductive layer 106 preferably has a thickness of about 1500 Å.

As shown in FIG. 1B, the conductive layer 106 and the gate dielectric layer 104 are patterned to form a gate structure 108. The gate structure 108 includes a portion of the original gate conductive layer 106, now referred to as 107, and the gate dielectric layer 104. The gate structure 108 is formed, for example, by conducting photolithographic and etching processes. Using the gate structure 108 as a mask, an ion implantation 110 is carried out to form lightly doped regions in the substrate 100. The lightly doped regions form what is called lightly doped drain (LDD) regions 112. The lightly doped regions are formed, for example, by implanting arsenic or phosphorus ions with an energy level of about 40 to 80 KeV and at a dosage of about 5×10¹² to 5×10¹⁴ ions/cm².

As shown in FIG. 1C, a conformal low dielectric constant material layer 114 is formed over the substrate 100. The low dielectric constant material layer 114 is formed from a dielectric material having a dielectric constant below 3 such as fluorinated silicate glass (FSG), organosilicate glass (OSG), parylene, fluorinated amorphous carbon (FLAC) or hydrogen silsesquioxane (HSQ). The low dielectric constant (low-k) material layer 114, preferably having a thickness of about 100 Å, is formed, for example, by chemical vapor deposition. A dielectric layer 116 is formed over the low dielectric constant material layer 114. The dielectric layer 116 preferably having a thickness of about 600 Å can be a silicon nitride layer or a silicon oxide layer formed, for example, by chemical vapor deposition.

As shown in FIG. 1D, a portion of the low dielectric constant material layer 114 and a portion of the dielectric layer 116 are removed to form a composite spacer 118 on each sidewall of the gate structure 108. The composite spacer 118 comprises a low dielectric constant material spacer 118a and a dielectric spacer 118b. The low dielectric constant material spacer 118a is located in the junction area between the dielectric spacer 118b and the gate structure 108 and in the junction area between the dielectric spacer 118b and the substrate 100. Material in the low dielectric constant material layer and material in the dielectric layer 116 are removed, for example, by conducting an anisotropic etching. Another ion implantation 120 of the substrate 100 is conducted using the gate structure 108 and the spacers 118 as a mask so that heavily doped source/drain regions 122 are formed in the substrate 100 on each side of the gate structure 108. The heavily doped regions 122 are formed, for example, by implanting arsenic or phosphorus ions with an energy level between about 50 to 100 KeV and at a dosage between about 1×10¹⁵ to 8×10¹⁵ ions/cm². Finally, other processing necessary for forming a complete MOS field effect transistor is conducted. Since these steps are familiar to anybody skilled in semiconductor production process, detailed description is omitted.

FIG. 1D is a complete cross-sectional view of a MOS field effect transistor fabricated according to a first embodiment of this invention. As shown in FIG. 1D, the MOS transistor includes a substrate 100, a gate structure 108 over the substrate 100, a dielectric spacer 118b on each sidewall of the gate structure 108, a low dielectric constant material spacer 118a in the junction area between the dielectric spacer 116b and the gate 108 and in the junction area between the dielectric spacer 118b and the substrate 100, and a source/drain region 122 in the substrate 100 on each side of the gate structure 108. The gate structure further includes a gate conductive layer 107 and a gate dielectric layer 104 between the gate conductive layer 107 and the substrate 100. The MOS transistor also includes a lightly doped source/drain region 112 underneath the low dielectric constant spacer 118a and the dielectric spacer 118b and adjacent to the source/drain region 122.

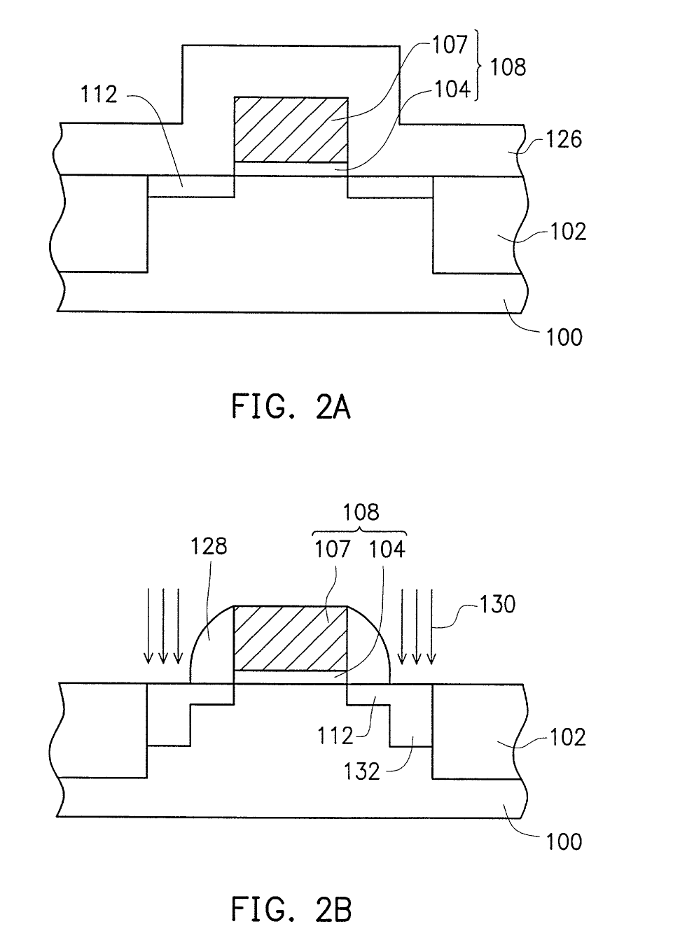

FIGS. 2A and 2B are schematic cross-sectional views showing the progression of steps for producing a MOS field effect transistor according to a second preferred embodiment of this invention. The second embodiment of this invention is based on the structure shown in FIG. 1B. Hence, components in FIGS. 2A and 2B having a component corresponding to one in FIG. 1B are labeled identically.

As shown in FIG. 2A, a low dielectric constant material layer 126 is formed over the substrate 100. The low dielectric constant material layer 126 is formed from a dielectric material having a dielectric constant below 3 such as fluorinated silicate glass (FSG), organosilicate glass (OSG), parylene, fluorinated amorphous carbon (FLAC) or hydrogen silsesquioxane (HSQ) and so on. The low dielectric constant (low-k) material layer 126, preferably having a thickness of about 700 Å, is formed, for example, by chemical vapor deposition.

As shown in FIG. 2B, a portion of the low dielectric constant material layer 126 is removed to form a low dielectric constant material spacer 128 on each sidewall of the gate structure 108. Material is removed from the low dielectric constant material layer 126 by anisotropic etching, for example. Another ion implantation 130 of the substrate 100 is conducted using the gate structure 108 and the spacers 128 as a mask so that heavily doped source/drain regions 132 are formed in the substrate 100 on each side of the gate structure 108. The heavily doped regions 132 are formed, for example, by implanting arsenic or phosphorus ions with an energy level of about 50 to 100 KeV and at a dosage of about 1×10¹⁵ to 8×10¹⁵ ions/cm². Finally, other processing necessary for forming a complete MOS field effect transistor is conducted. Since these steps are familiar to anybody skilled in semiconductor production process, detailed description is omitted.

FIG. 2B is a complete cross-sectional view of a MOS field effect transistor fabricated according to a second embodiment of this invention. As shown in FIG. 2B, the MOS transistor includes a substrate 100, a gate structure 108 over the substrate 100, a dielectric spacer 128 on each sidewall of the gate structure 108 and a source/drain region 132 in the substrate 100 on each side of the gate structure 108. The gate structure further includes a gate conductive layer 107 and a gate dielectric layer 104 between the gate conductive layer 107 and the substrate 100. The MOS transistor also includes a lightly doped source/drain region 112 underneath the low dielectric constant spacer 128 and adjacent to the source/drain region 132.

In conclusion, this invention provides a method suitable for producing deep submicron MOS field effect transistors. Using low dielectric constant material to replace conventional silicon nitride or silicon oxide material, parasitic capacitance of the transistor devices is reduced so that a faster operating speed is possible.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of producing a type of metal-oxide-semiconductor field effect transistor, comprising:
providing a substrate;
forming a gate dielectric layer over the substrate;
forming a conductive layer over the gate dielectric layer;
patterning the conductive layer and the gate dielectric layer to form a gate structure;
forming a low dielectric constant material spacer on each sidewall of the gate structure; and
forming a source/drain region in the substrate on each side of the gate structure.

2. The method of claim 1, wherein a low dielectric constant material spacer material is selected from a group consisting of fluorinated silicate glass (FSG), organosilicate glass (OSG), parylene, fluorinated amorphous carbon (FLAC) hydrogen silsesquioxane (HSQ).

3. The method of claim 1, wherein forming the low dielectric constant material spacer further includes:
forming a low dielectric constant material layer over the substrate; and
removing a portion of the low dielectric constant material from the layer so that a remaining portion of the low dielectric constant material layer forms the spacer.

4. The method of claim 3, wherein a low dielectric constant material spacer material is selected from a group consisting of fluorinated silicate glass (FSG), organosilicate glass (OSG), parylene, fluorinated amorphous carbon (FLAC) hydrogen silsesquioxane (HSQ).

5. The method of claim 3, wherein forming the low dielectric constant material layer includes conducting a chemical vapor deposition process.

6. The method of claim 3, wherein removing a portion of the low dielectric constant material layer includes conducting anisotropic etching.

7. The method of claim 1, wherein after forming the gate structure, a lightly doped source/drain region is further formed in the substrate on each side of the gate structure while using the gate structure as a mask.

8. A method of producing a type of metal-oxide-semiconductor field effect transistor, comprising:
providing a substrate;
forming a gate dielectric layer over the substrate;
forming a conductive layer over the gate dielectric layer;
patterning the conductive layer and the gate dielectric layer to form a gate structure;
forming a low dielectric constant material layer over the substrate;
forming a dielectric layer over the low dielectric constant material layer;
removing a portion of the dielectric layer and a portion of the low dielectric constant material layer so that a composite spacer is formed on each sidewall of the gate structure; and
forming a source/drain region in the substrate on each side of the gate structure.

9. The method of claim 8, wherein a low dielectric constant material spacer material is selected from a group consisting of fluorinated silicate glass (FSG), organosilicate glass (OSG), parylene, fluorinated amorphous carbon (FLAC) and hydrogen silsesquioxane (HSQ).

10. The method of claim 8, wherein a dielectric layer material is selected from a group consisting of silicon nitride and silicon oxide.

11. The method of claim 8, wherein forming the low dielectric constant material layer includes conducting a chemical vapor deposition process.

12. The method of claim 8, wherein removing a portion of the low dielectric constant material layer and a portion of the dielectric layer includes conducting an anisotropic etching.

13. The method of claim 8, wherein after forming the gate structure, a lightly doped source/drain region is further formed in the substrate on each side of the gate structure while using the gate structure as a mask.

14. A metal-oxide-semiconductor (MOS) field effect transistor, comprising:
a substrate;
a gate structure over the substrate;
a low dielectric constant material spacer on each sidewall of the gate structure; and
a source/drain region in the substrate on each side of the gate structure.

15. The MOS transistor of claim 14, wherein a low dielectric constant material spacer material is selected from a group consisting of fluorinated silicate glass (FSG), organosilicate glass (OSG), parylene, fluorinated amorphous carbon (FLAC) and hydrogen silsesquioxane (HSQ).

16. The MOS transistor of claim 14, wherein the gate structure further comprises:
a gate conductive layer over the substrate; and
a gate dielectric layer between the gate conductive layer and the substrate.

17. The MOS transistor of claim 14, wherein the transistor further includes a lightly doped source/drain region underneath the low dielectric constant spacer and adjacent to the source/drain region.

18. A metal-oxide-semiconductor (MOS) field effect transistor, comprising:
a substrate;
a gate structure over the substrate;
a dielectric spacer on each sidewall of the gate structure;
a low dielectric constant material spacer in a junction area between the dielectric spacer and the gate structure and in a junction area between the dielectric spacer and the substrate; and
a source/drain region in the substrate on each side of the gate structure.

19. The MOS transistor of claim 18, wherein a low dielectric constant material spacer material is selected from a group consisting of fluorinated silicate glass (FSG), organosilicate glass (OSG), parylene, fluorinated amorphous carbon (FLAC) and hydrogen silsesquioxane (HSQ).

20. The method of claim 18, wherein a dielectric layer material is selected from a group consisting of silicon nitride and silicon oxide.

21. The MOS transistor of claim 18, wherein the gate structure further comprises:
a gate conductive layer over the substrate; and
a gate dielectric layer between the gate conductive layer and the substrate.

22. The MOS transistor of claim 18, wherein the transistor further includes a lightly doped source/drain region underneath the dielectric spacer and the low dielectric constant spacer adjacent to the source/drain region.
